(19) United States
(12) Patent Application Publication
(10) Pub. No.: US 2026/0371996 A1
(43) Pub. Date: Nov. 19, 2026

(54) SUBSTRATE PROCESSING APPARATUS AND METHOD OF DETECTING INTERNAL STATE OF PROCESSING CONTAINER

(71) Applicant: Tokyo Electron Limited, Tokyo (JP)

(72) Inventors: Mitsuki TERUI, Kumamoto (JP); Shigeru MORIYAMA, Kumamoto (JP); Tomotaka OMAGARI, Kumamoto (JP); Shinichi IKEDA, Kumamoto (JP)

(21) Appl. No.: 19/408,708

(22) Filed: Dec. 4, 2025

(30) Foreign Application Priority Data
Dec. 6, 2024 (JP) 2024-213279

(51) Int. Cl. H10P 72/00; H10P 72/30; H10P 72/50

(52) U.S. Cl. CPC H10P 72/0608; H10P 72/0408; H10P 72/0414; H10P 72/3306; H10P 72/53

(57) ABSTRACT

A substrate processing apparatus includes: a processing container having a processing space capable of accommodating a substrate and a loading/unloading port through which the substrate is loaded into and unloaded from the processing space; a capturer configured to capture an image of a capturing region including the loading/unloading port and the processing space of the processing container, which is exposed through the loading/unloading port; and a controller configured to detect a state of the substrate inside the processing container based on a luminance value of the image captured by the capturer.

### CROSS-REFERENCE TO RELATED APPLICATION

This application is based upon and claims the benefit of priority from Japanese Patent Application No. 2024-213279, filed on Dec. 6, 2024, the entire contents of which are incorporated herein by reference.

### TECHNICAL FIELD

The present disclosure relates to a substrate processing apparatus and a method of detecting an internal state of a processing container.

### BACKGROUND

Patent Document 1 discloses a technique in which, when a substrate is loaded into a processing container, an image of a substrate loading/unloading port of the processing container is captured by a camera provided on a transfer arm that transfers the substrate, and the image captured by the camera is compared with a reference image to detect an internal state of the processing container.

### PRIOR ART DOCUMENT

### Patent Document

Patent Document 1: Japanese Laid-Open Publication No. 2005-175083

### SUMMARY

According to one embodiment of the present disclosure, a substrate processing apparatus includes: a processing container having a processing space capable of accommodating a substrate and a loading/unloading port through which the substrate is loaded into and unloaded from the processing space; a capturer configured to capture an image of a capturing region including the loading/unloading port and the processing space of the processing container, which is exposed through the loading/unloading port; and a controller configured to detect a state of the substrate inside the processing container based on a luminance value of the image captured by the capturer.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a diagram illustrating a configuration of a substrate processing apparatus according to an embodiment.

FIG. 2 is a diagram illustrating a configuration of a liquid processing unit according to an embodiment.

FIG. 3 is a side cross-sectional view schematically illustrating a configuration of a drying unit according to an embodiment.

FIG. 4 is a side cross-sectional view schematically illustrating the configuration of the drying unit according to an embodiment.

FIG. 5 is a side cross-sectional view schematically illustrating the configuration of the drying unit according to an embodiment.

FIG. 6 is a cross-sectional view taken along line VI-VI in FIG. 3.

FIG. 7 is an enlarged view illustrating configurations of an illuminator and surrounding components thereof according to an embodiment.

FIG. 8 is a cross-sectional view taken along line VIII-VIII in FIG. 7.

FIG. 9 is a flowchart illustrating a process sequence executed by the substrate processing apparatus according to an embodiment.

FIG. 10 is a flowchart illustrating a sequence of a first detection process of detecting an internal state of a first processing container according to an embodiment.

FIG. 11 is a flowchart illustrating a sequence of a process of detecting the presence or absence of a substrate, which is executed by a controller according to an embodiment.

FIG. 12 is a diagram for explaining a first process according to an embodiment.

FIG. 13 is a diagram for explaining the first process according to the embodiment.

FIG. 14 is a diagram for explaining the first process according to the embodiment.

FIG. 15 is a diagram for explaining a second process according to an embodiment.

FIG. 16 is a diagram for explaining a third process according to an embodiment.

FIG. 17 is a diagram for explaining the third process according to the embodiment.

FIG. 18 is a flowchart illustrating a sequence of a second detection process of detecting an internal state of a second processing container according to an embodiment.

FIG. 19 is a flowchart illustrating a sequence of a process of detecting whether or not the substrate has been detached, which is executed by the controller according to an embodiment.

FIG. 20 is a diagram illustrating another example of the third process according to an embodiment.

FIG. 21 is a diagram illustrating another example of the third process according to an embodiment.

FIG. 22 is a flowchart illustrating a sequence of a process of detecting whether or not the substrate has been detached, which is executed by the controller according to Modification 1 of the embodiment.

FIG. 23 is a diagram for explaining a fourth process according to Modification 1 of the embodiment.

FIG. 24 is a diagram for explaining a fifth process according to Modification 1 of the embodiment.

FIG. 25 is a diagram for explaining a sixth process according to Modification 1 of the embodiment.

FIG. 26 is a diagram for explaining a seventh process according to Modification 1 of the embodiment.

FIG. 27 is a diagram for explaining an eighth process according to Modification 1 of the embodiment.

FIG. 28 is a flowchart illustrating a sequence of a process of detecting whether or not the substrate has been detached, which is executed by the controller according to Modification 2 of the embodiment.

FIG. 29 is a diagram for explaining a ninth process according to Modification 2 of the embodiment.

FIG. 30 is a diagram for explaining a tenth process according to Modification 2 of the embodiment.

### DETAILED DESCRIPTION

Hereinafter, modes (hereinafter referred to as “embodiments”) for implementing a substrate processing apparatus and a method of detecting an internal state of a processing container according to the present disclosure will be described in detail with reference to the accompanying drawings. Further, the present disclosure is not limited by the embodiments. In addition, these embodiments may be appropriately combined with each other to the extent that they are not contradictory. Further, in each of the following embodiments, the same components will be denoted by same reference numerals, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In addition, in the embodiments described below, expressions such as “constant,” “orthogonal,” “vertical,” or “parallel” may be used. These expressions do not necessary mean strictly “constant,” “orthogonal,” “vertical,” or “parallel.” In other words, each of the above expressions allow for deviations and tolerances in manufacturing accuracy, installation accuracy, or the like.

Further, in each of the drawings referenced to below, in order to facilitate ease of understanding the descriptions, an orthogonal coordinate system may be defined in which an X-axis direction, a Y-axis direction, and a Z-axis direction are orthogonal to one another, and the Z-axis positive direction is referred to as a vertically upward direction. Further, a direction of rotation about a vertical axis may be referred to as a θ direction.

In Patent Document 1, there is disclosed the technique in which, when a substrate is loaded into a processing container, an image of a substrate loading/unloading port of the processing container is captured by a camera provided on a transfer arm that transfers the substrate, and the image captured by the camera is compared with a reference image to detect an internal state of the processing container.

However, in the technique of comparing the captured image with the reference image, high-speed processing is difficult, which makes it difficult to efficiently detect the internal state of the processing container. Therefore, a technique capable of efficiently detecting the internal state of the processing container is needed.

### EMBODIMENTS

### Configuration of Substrate Processing Apparatus

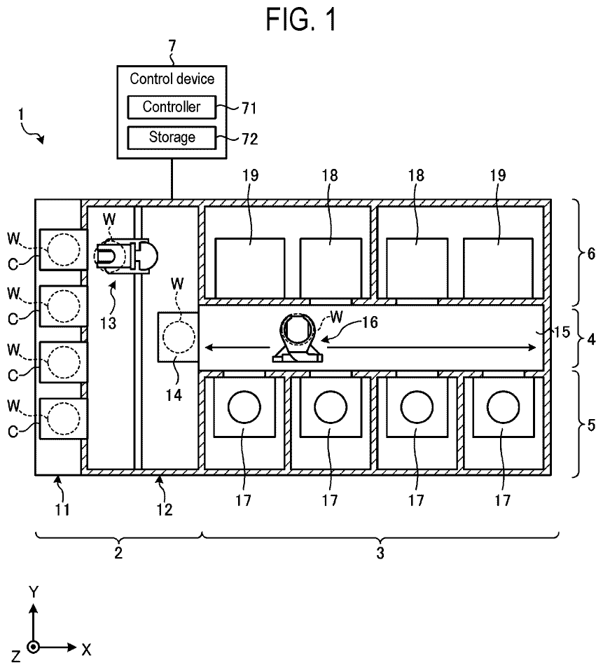

Hereinafter, a configuration of a substrate processing apparatus according to an embodiment will be described with reference to FIG. 1. FIG. 1 is a diagram illustrating the configuration of the substrate processing apparatus according to the embodiment.

As illustrated in FIG. 1, a substrate processing apparatus 1 includes a loading/unloading station 2 and a processing station 3. The loading/unloading station 2 and the processing station 3 are provided to be adjacent to each other.

The loading/unloading station 2 includes a carrier placement part 11 and a transfer part 12. A plurality of carriers C, each of which accommodates a plurality of semiconductor wafers W (hereinafter referred to as “wafers W”) in a horizontal posture, is placed on the carrier placement part 11.

The transfer part 12 is provided to be adjacent to the carrier placement part 11. A transfer device 13 and a deliverer 14 are disposed inside the transfer part 12.

The transfer device 13 includes a wafer holding mechanism that holds the wafer W. In addition, the transfer device 13 is movable horizontally and vertically and is swingable about a vertical axis thereof. The transfer device 13 transfers the wafer W between the carriers C and the deliverer 14 using the wafer holding mechanism.

The processing station 3 is provided to be adjacent to the transfer part 12. The processing station 3 includes a transfer block 4, a first processing block 5, and a second processing block 6.

The transfer block 4 includes a transfer area 15 and a transfer device 16. The transfer area 15 is, for example, an area of a rectangular parallelepiped shape which extends in a direction (the X-axis direction) in which the loading/unloading station 2 and the processing station 3 are arranged. The transfer device 16 is disposed in the transfer area 15.

The transfer device 16 includes a wafer holding mechanism that holds the wafer W. The transfer device 16 is movable horizontally and vertically and is swingable about a vertical axis thereof. The transfer device 16 transfers the wafer W between the deliverer 14, the first processing block 5, and the second processing block 6 using the wafer holding mechanism.

The first processing block 5 and the second processing block 6 are disposed to be adjacent to the transfer area 15 on both sides of the transfer area 15. Specifically, the first processing block 5 is disposed on one side of the transfer area 15 (a negative side in the Y-axis direction) in a direction (the Y-axis direction) orthogonal to the direction (the X-axis direction) in which the loading/unloading station 2 and the processing station 3 are arranged. In addition, the second processing block 6 is disposed on the other side of the transfer area 15 (a positive side in the Y-axis direction) in the direction (the Y-axis direction) orthogonal to the direction (the X-axis direction) in which the loading/unloading station 2 and the processing station 3 are arranged.

The first processing block 5 includes liquid processing units 17.

The liquid processing unit 17 performs a cleaning process of cleaning an upper surface of the wafer W, which is a pattern formation surface. Further, the liquid processing unit 17 performs a liquid film formation process of forming a liquid film on the upper surface of the wafer W which has been subjected to the cleaning process. A configuration of the liquid processing unit 17 will be described later.

The second processing block 6 includes drying units 18 and supply units 19.

The drying unit 18 performs a supercritical drying process on the wafer W which has been subjected to the liquid film formation process. Specifically, the drying unit 18 dries the wafer W by bringing the wafer W, which has been subjected to the liquid film formation process, into contact with a processing fluid in a supercritical state (hereinafter, also referred to as “supercritical fluid”). A configuration of the drying unit 18 will be described later.

The supply unit 19 supplies the processing liquid to the drying unit 18. Specifically, the supply unit 19 is provided with a supply device group including a flowmeter, a flow regulator, a backing pressure valve, a heater, and the like, and a housing which accommodates the supply device group. In this embodiment, the supply unit 19 supplies CO₂ as the processing fluid to the drying unit 18.

The substrate processing apparatus 1 includes a control device 7. The control device 7 is, for example, a computer, and includes a controller 71 and a storage 72.

The controller 71 includes a microcomputer including a central processing unit (CPU), a read only memory (ROM), a random access memory (RAM), input/output ports, and the like, and various kinds of circuits. The CPU of the microcomputer reads out and executes a program stored in the ROM so as to control the transfer devices 13 and 16, the liquid processing units 17, the drying units 18, the supply units 19, and the like.

Such a program may be recorded in a non-transitory computer-readable storage medium and installed in the storage 72 of the control device 7 from the storage medium. The computer-readable recording medium includes, for example, a hard disk (HD), a flexible disk (FD), a compact disc (CD), a magneto-optical disk (MO), a memory card, and the like.

The storage 72 is implemented by, for example, a semiconductor memory device such as a RAM or a flash memory, or a storage device such as a hard disk or an optical disk.

### Configuration of Liquid Processing Unit

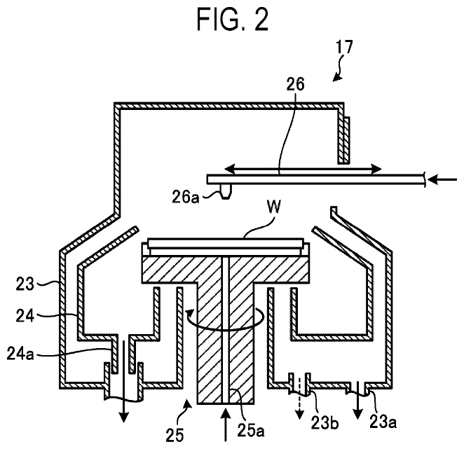

Next, the configuration of the liquid processing unit 17 will be described with reference to FIG. 2. FIG. 2 is a diagram illustrating the configuration of the liquid processing unit 17 according to an embodiment. The liquid processing unit 17 is configured as a single-wafer cleaning device which cleans the wafers W one by one by, for example, spin cleaning.

As illustrated in FIG. 2, the liquid processing unit 17 holds the wafer W substantially in a horizontal posture with a wafer holding mechanism 25 disposed inside an outer chamber 23 in which a processing space is defined, and rotates the wafer W by rotating the wafer holding mechanism 25 around a vertical axis thereof. Further, the liquid processing unit 17 moves a nozzle arm 26 to above the wafer W being rotated, and supplies a chemical liquid or a rinse liquid in a predetermined order from a chemical liquid nozzle 26a provided at a tip of the nozzle arm 26, thus performing the cleaning process on a front surface of the wafer W.

The liquid processing unit 17 includes a gas supply passage 25a provided inside the wafer holding mechanism 25. The liquid processing unit 17 supplies a gas supplied through the gas supply passage 25a, for example, an inert gas such as a nitrogen gas, to a central portion of a back surface of the wafer W.

For example, the cleaning process includes removing particles or organic contaminants with an SC1 liquid (mixed solution of ammonia and hydrogen peroxide), which is an alkaline chemical liquid, and subsequently performing a rinse cleaning with deionized water (hereinafter, referred to as “DIW”), which is a rinse liquid. Further, the cleaning process includes removing a natural oxide film with a diluted hydrofluoric acid (hereinafter, referred to as “DHF”), which is an acid chemical liquid, and subsequently performing the rinse cleaning with DIW.

The various kinds of chemical liquids as described above are received in the outer chamber 23 or an inner cup 24 disposed inside the outer chamber 23, and are discharged via a drain port 23a provided in a bottom of the outer chamber 23 or a drain port 24a provided in a bottom of the inner cup 24. Further, an internal atmosphere of the outer chamber 23 is exhausted via an exhaust port 23b provided in the bottom of the outer chamber 23.

The liquid film formation process is performed after the rinse cleaning of the cleaning process. Specifically, the liquid processing unit 17 supplies an IPA liquid to the front surface and the back surface of the wafer W while rotating the wafer holding mechanism 25. Thus, DIW remaining on both surfaces of the wafer W is replaced with IPA.

At this time, the liquid processing unit 17 supplies a gas from the gas supply passage 25a to the central portion of the back surface of the wafer W. The gas supplied to the central portion of the back surface of the wafer W flows toward an outer peripheral portion of the back surface of the wafer W along the back surface of the wafer W. Thus, during the liquid film formation process by the liquid processing unit 17, it is possible to suppress IPA supplied to the front surface of the wafer W from flowing toward the back surface of the wafer W. Thereafter, the liquid processing unit 17 gradually stops the rotation of the wafer holding mechanism 25.

The wafer W, which has been subjected to the liquid film formation process and has an IPA liquid film formed on the front surface thereof, is delivered to the transfer device 16 by a delivery mechanism provided in the wafer holding mechanism 25 and is unloaded from the liquid processing unit 17. The liquid film formed on the wafer W prevents the liquid on the front surface of the wafer W from evaporating (vaporizing) during the transfer of the wafer W from the liquid processing unit 17 to the drying unit 18 or during the loading of the wafer W into the drying unit 18, and prevents a collapse of patterns on the wafer W.

### Configuration of Drying Unit

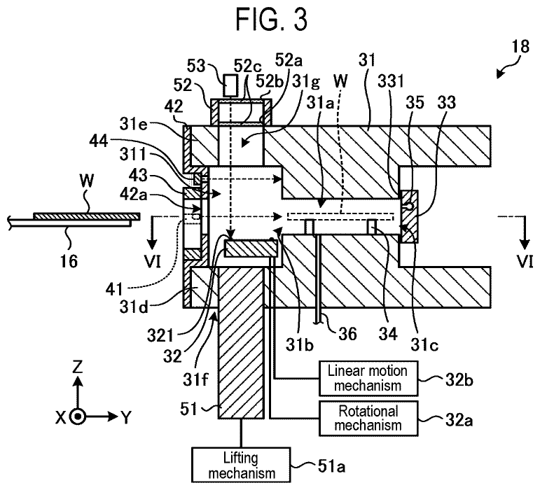

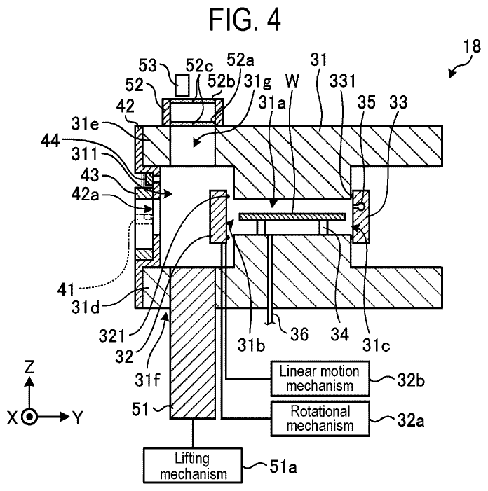

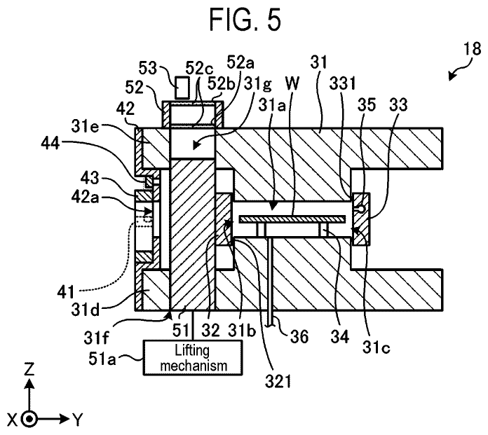

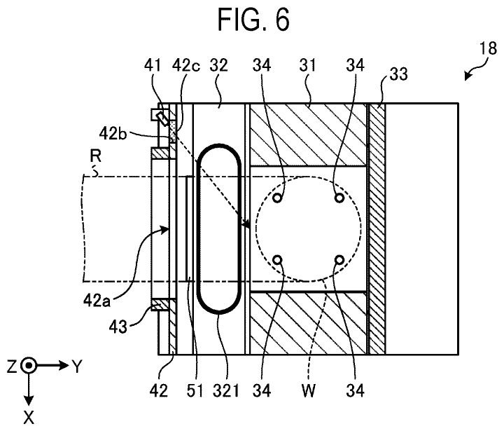

Next, a configuration of the drying unit 18 will be described with reference to FIGS. 3 to 8. FIGS. 3 to 5 are side cross-sectional views schematically illustrating the configuration of the drying unit 18 according to an embodiment. FIG. 6 is a cross-sectional view taken along line VI-VI in FIG. 3. Further, in FIG. 3, a cover 32 at a standby position is illustrated. In FIG. 4, the cover 32 at an open position is illustrated. In FIG. 5, the cover 32 at a closed position is illustrated.

As illustrated in FIGS. 3 to 5, the drying unit 18 includes a processing container 31, the cover 32, a cover 33, and a plurality of support pins 34.

The processing container 31 has a processing space 31a provided therein to accommodate the wafer W having a diameter of, for example, 300 mm. When the supercritical drying process is performed on the wafer W, the processing space 31a provided in the processing container 31 is pressurized.

The processing container 31 has, for example, a rectangular shape in a plan view, and includes a loading/unloading port 31b provided on a side surface facing the transfer area 15 among a plurality of (four in this example) side surfaces and through which the wafer W is loaded into and unloaded from the processing space 31a. Further, the processing container 31 includes a maintenance port 31c at a position facing the loading/unloading port 31b with the processing space 31a interposed therebetween. The processing space 31a is brought into communication with the outside via the maintenance port 31c. The maintenance port 31c is used, for example, when performing maintenance on the processing container 31.

The cover 32 is disposed on one end side of the processing container 31 (the negative side in the Y-axis direction) in a transfer direction of the wafer W (the Y-axis direction).

The cover 32 is configured to be capable of closing the loading/unloading port 31b of the processing container 31. That is, the cover 32 is connected to a rotational mechanism 32a and a linear motion mechanism 32b. By the rotational mechanism 32a, the cover 32 may rotate between the standby position illustrated in FIG. 3 and the open position illustrated in FIG. 4.

By the linear motion mechanism 32b, the cover 32 may move between the open position illustrated in FIG. 4 and the closed position illustrated in FIG. 5. In this way, the cover 32 opens or closes the loading/unloading port 31b. The closed position refers to a position at which the cover 32 closes the loading/unloading port 31b via a sealing member 321. The open position refers to a position spaced apart from the closed position in a direction in which the wafer W is unloaded from the processing space 31a (for example, a negative Y-axis direction). The standby position refers to a position at which the cover 32 does not interfere with a wafer transfer path R (see FIG. 6) with respect to the processing space 31a. When the cover 32 is at the standby position, the loading/unloading port 31b is not closed by the cover 32. In this case, the transfer device 16 may load the wafer W into the processing space 31a via the loading/unloading port 31b while holding the wafer W. Further, when the cover 32 is at the standby position, a portion of the sealing member 321 faces a second insertion hole 31g to be described later. As the sealing member 321, for example, an O-ring may be used.

The cover 33 is disposed on the other end side of the processing container 31 (a positive Y-axis direction) in the transfer direction of the wafer W (the Y-axis direction). The cover 33 closes the maintenance port 31c of the processing container 31. The cover 33 closes the maintenance port 31c via a sealing member 331. As the sealing member 331, for example, an O-ring may be used.

As described above, both ends of the processing space 31a in the transfer direction of the wafer W are open. The loading/unloading port 31b and the maintenance port 31c are respectively closed by the covers 32 and 33 so that the processing space 31a is closed.

The cover 33 is provided with a supply port 35. The supply port 35 is connected to a supply line (not illustrated) which supplies the supercritical fluid to the drying unit 18. In addition, the processing space 31a is provided with a discharge port 36. The discharge port 36 is connected to a discharge line (not illustrated) which discharges the supercritical fluid and other fluids from the drying unit 18.

The supply port 35 remains open horizontally toward the processing space 31a. The supercritical fluid supplied from the supply line (not illustrated) flows horizontally from the maintenance port 31c toward the loading/unloading port 31b inside the processing space 31a.

The discharge port 36 is disposed in the vicinity of the loading/unloading port 31b. For example, the discharge port 36 may be open downward of the processing space 31a in the vicinity of the loading/unloading port 31b. The supercritical fluid flowing toward the loading/unloading port 31b in the processing space 31a is discharged outward of the processing space 31a from the discharge port 36 via a discharge line (not illustrated). In addition, the supercritical fluid discharged outward of the processing space 31a may contain the IPA liquid that has been dissolved in the supercritical fluid remaining in the supercritical state in the front surface of the wafer W.

The plurality of support pins 34 is provided below the processing space 31a to support the wafer W while spacing the wafer W apart from a lower portion of the processing space 31a.

In the drying unit 18 configured as above, the IPA liquid existing between patterns formed on the wafer W gradually dissolves in the supercritical fluid while being in contact with the supercritical fluid kept in a high pressure state (for example, 16 MPa) so that a space between the patterns is gradually replaced with the supercritical fluid. Eventually, the space between the patterns is filled only with the supercritical fluid.

Next, after the IPA liquid is removed from between the patterns, an internal pressure of the processing container 31 kept in the high pressure state is reduced to atmospheric pressure.

As a result, CO₂ transitions from the supercritical state to a gaseous state so that the space between the patterns is filled with the gas. In this way, the IPA liquid between the patterns is removed so that the drying process on the wafer W is completed.

The supercritical fluid has a lower viscosity and higher liquid solubility than those of a liquid (such as the IPA liquid). In addition, an interface is hardly present between the supercritical fluid and a liquid or gas that is in equilibrium with the supercritical fluid. As a result, in the drying process using the supercritical fluid, the liquid may be dried without being affected by surface tension. Therefore, according to the embodiment, it is possible to suppress the collapse of the patterns during the drying process.

In this embodiment, there has been described the example in which the IPA liquid is used as an anti-drying liquid and CO₂ in the supercritical state is used as the processing fluid.

However, a liquid other than IPA may be used as the anti-drying liquid, and a fluid other than the supercritical CO₂ may be used as the processing fluid.

The processing container 31 includes a first protrusion 31d and a second protrusion 31e which protrude in an unloading direction (toward the negative side of the Y-axis direction) in which the wafer W is unloaded from the processing space 31a rather than toward the loading/unloading port 31b. The first protrusion 31d protrudes toward the negative side of the Y-axis direction from below the loading/unloading port 31b, and the second protrusion 31e protrudes toward the negative side of the Y-axis direction from above the loading/unloading port 31b.

The first protrusion 31d has a first insertion hole 31f through which upper and lower surfaces of the first protrusion 31d are in communication with each other. Further, the second protrusion 31e has the second insertion hole 31g formed at a position facing the first insertion hole 31f in the vertical direction and through which upper and lower surfaces of the second protrusion 31e are in communication with each other. A locking member 51 (to be described later) is inserted through the first insertion hole 31f and the second insertion hole 31g.

In addition, the processing container 31 includes a shielding plate 42 which blocks a space 311 between the first protrusion 31d and the second protrusion 31e on the negative side of the Y-axis direction. The shielding plate 42 has a recess which is depressed toward the space 311. A capturer 41 and an illuminator 44, which will be described later, are accommodated in the recess.

The shielding plate 42 has an opening 42a through which the wafer W passes at a position facing the loading/unloading port 31b via the space 311. In addition, the processing container 31 may include other shielding plates (not illustrated) which block two side surfaces of the space 311 (surfaces on positive and negative sides in the X-axis direction in this example).

As illustrated in FIGS. 3 and 6, the drying unit 18 includes the capturer 41. The capturer 41 captures an image of a capturing region including the loading/unloading port 31b and the processing space 31a of the processing container 31, which is exposed through the loading/unloading port 31b, in a state in which the loading/unloading port 31b is not closed by the cover 32.

The capturer 41 is disposed at a position that does not overlap with the transfer path R of the wafer W in a plan view when the wafer W is transferred into the processing space 31a via the loading/unloading port 31b. Specifically, the capturer 41 is disposed on an outer surface which is not in contact with the space 311 in the shielding plate 42 and at a position adjacent to the opening 42a along a width direction of the transfer path R of the wafer W (the X-axis direction in this example).

The shielding plate 42 has a through-hole 42b formed at a position adjacent to the opening 42a in the width direction of the transfer path R of the wafer W. The through-hole 42b is closed by a transparent member 42c. The capturer 41 captures an image of the capturing region from the outer surface of the shielding plate 42 via the transparent member 42c.

As described above, in the drying unit 18 according to an embodiment, it is possible to appropriately detect the internal state of the processing container 31 by capturing, using the capturer 41, the image of the capturing region including the loading/unloading port 31b and the processing space 31a of the processing container 31 exposed through the loading/unloading port 31b. In this case, for example, when the wafer W is loaded into the processing container 31, the drying unit 18 may detect whether or not any other wafers are present inside the processing container 31. This makes it possible to reduce a matter in which the wafer W being loaded may be damaged by collision with other wafers.

Further, since the capturer 41 is disposed at the position that does not overlap with the transfer path R of the wafer in a plan view, the capturer 41 and the wafer W may be prevented from being interfered with each other even when the transfer device 16 loads the wafer W into the processing space 31a via the loading/unloading port 31b.

Further, the capturer 41 captures an image of the capturing region from the outer surface of the shielding plate 42 via the transparent member 42c. With this configuration, the capturer 41 may perform such a capturing process without being exposed to an internal atmosphere of the space 311 between the first protrusion 31d and the second protrusion 31e. This may suppress the capturer 41 from malfunctioning due to the exposure to the internal atmosphere of the space 311.

A partition wall 43 is disposed on the shielding plate 42. The partition wall 43 is disposed at a position surrounding an outer periphery of the opening 42a on the outer surface of the shielding plate 42, and isolates the opening 42a from the capturer 41. With this configuration, the capturer 41 may perform the capturing process without being exposed to the internal atmosphere of the space 311 between the first protrusion 31d and the second protrusion 31e. This may suppress the capturer 41 from malfunctioning due to the exposure to the internal atmosphere of the space 311.

As illustrated in FIGS. 3 to 5, the drying unit 18 includes the illuminator 44. The illuminator 44 illuminates at least a predetermined region around the loading/unloading port 31b in the capturing region to be captured by the capturer 41. Specifically, the illuminator 44 illuminates the predetermined region defined above the loading/unloading port 31b in the capturing region. In a case in which the capturing region to be captured by the capturer 41 is entirely illuminated, light reflected from the capturing region may hinder the capturing process by the capturer 41, which may cause a degradation in capturing accuracy of the capturing process.

In contrast, in the drying unit 18 according to the embodiment, the illuminator 44 illuminates at least the predetermined region around the loading/unloading port 31b rather than the entire capturing region. This reduces the reflected light from the capturing region and improves the capturing accuracy of the capturing process by the capturer 41. This makes it possible to more appropriately detect the internal state of the processing container 31.

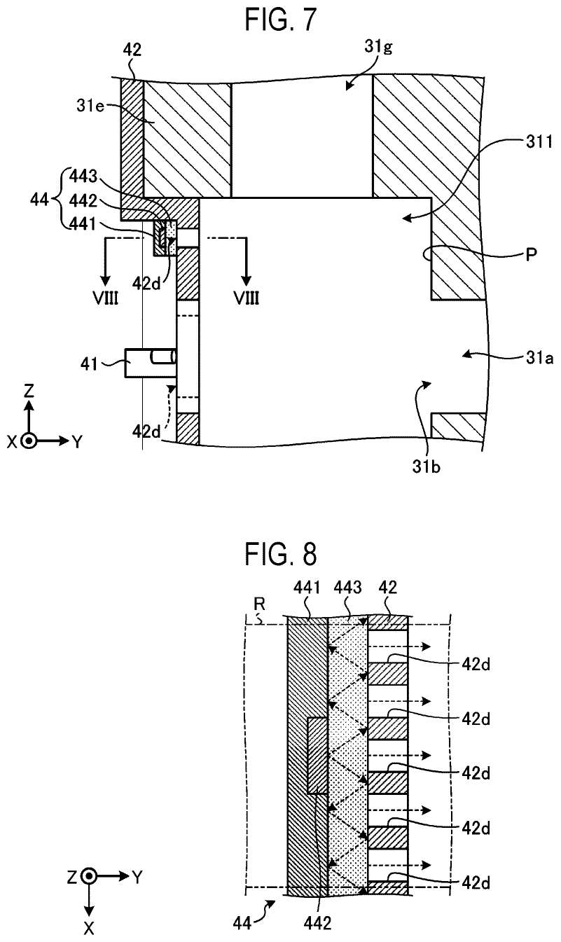

Next, configurations of the illuminator 44 and surrounding components thereof will be described with reference to FIGS. 7 and 8. FIG. 7 is an enlarged view illustrating the configurations of the illuminator 44 and the surrounding components thereof according to the embodiment. FIG. 8 is a cross-sectional view taken along line VIII-VIII in FIG. 7. For the sake of convenience in description, the illustration of the partition wall 43 around the shielding plate 42 is omitted in FIG. 7.

As illustrated in FIGS. 7 and 8, the shielding plate 42 has a plurality of through-holes 42d arranged in the width direction (the X-axis direction in this example) of the transfer path R of the wafer W at positions facing a predetermined region P around the loading/unloading port 31b, which is to be illuminated by the illuminator 44.

The illuminator 44 includes a fixing plate 441, a light source 442, and a light diffuser 443.

The fixing plate 441 is a plate-like member extending in the width direction of the transfer path R of the wafer W and faces the plurality of through-holes 42d of the shielding plate 42. The fixing plate 441 is connected to the shielding plate 42 by a connection member (not illustrated) such as a bolt with the light diffuser 443 disposed between the fixing plate 441 and the shielding plate 42. A recess is formed in a surface of the fixing plate 441, which faces the shielding plate 42, to fix the light source 442 therein.

The light source 442 is fixed to the fixing plate 441 and emits light. For example, the light source 442 is fixed to a bottom surface of the recess formed in the fixing plate 441.

The light diffuser 443 is a plate-like member extending in the width direction of the transfer path R of the wafer W and is disposed between the fixing plate 441 and the shielding plate 42. The light diffuser 443 diffuses the light emitted from the light source 442 in the width direction of the transfer path R of the wafer W and irradiates the predetermined region P around the loading/unloading port 31b with a portion of the diffused light via the plurality of through-holes 42d.

As described above, the illuminator 44 according to the embodiment uses the light diffuser 443 to diffuse the light in the width direction of the transfer path R of the wafer W and irradiates the predetermined region P around the loading/unloading port 31b with a portion of the diffused light via the plurality of through-holes 42d. This makes it possible to uniformly illuminate the entire predetermined region P around the loading/unloading port 31b.

As illustrated in FIGS. 3 to 5, the drying unit 18 includes the locking member 51. The locking member 51 is inserted into the first insertion hole 31f formed in the first protrusion 31d. A lifting mechanism 51a for raising and lowering the locking member 51 is connected to the locking member 51.

Next, an operation of the locking member 51 will be described. First, the drying unit 18 performs an operation of loading the wafer W. During the loading operation, the transfer device 16 transfers the wafer W held by the wafer holding mechanism on the support pins 34. Then, the drying unit 18 rotates the cover 32 from the standby position (see FIG. 3) to the open position (see FIG. 4) using the rotational mechanism 32a, and moves the cover 32 from the open position to the closed position (see FIG. 5) using the linear motion mechanism 32b. Thus, the loading/unloading port 31b of the processing container 31 is closed by the cover 32 and the processing space 31a is sealed. Subsequently, the drying unit 18 raises the locking member 51 using the lifting mechanism 51a to insert the locking member 51 into the second insertion hole 31g formed in the second protrusion 31e.

The locking member 51 is inserted into the second insertion hole 31g and is brought into contact with a surface opposite to a surface of the cover 32 which closes the loading/unloading port 31b, thereby restricting the movement of the cover 32 from the closed position to the open position. Thus, the locking member 51 may press the cover 33 toward the processing space 31a against internal pressure generated by the supercritical fluid supplied to the processing space 31a. This makes it possible to maintain a state in which the processing space 31a is sealed by the cover 33.

The drying unit 18 is provided with an exhaust duct 52. The exhaust duct 52 is disposed above the second insertion hole 31g. The exhaust duct 52 is in communication with the space 311 between the first protrusion 31d and the second protrusion 31e via an exhaust hole (not illustrated) formed in the second protrusion 31e. The exhaust duct 52 is connected to a pump (not illustrated) and discharges an internal atmosphere of the processing space 31a via the space 311 and the exhaust port.

The exhaust duct 52 has through-holes 52a and 52b formed at positions corresponding to the second insertion hole 31g. The through-hole 52a is formed at a bottom portion of the exhaust duct 52, and the through-hole 52b is formed at a ceiling portion of the exhaust duct 52. Each of the through-holes 52a and 52b is blocked by a transparent member 52c.

The drying unit 18 includes an additional capturer 53. The additional capturer 53 captures an image of the sealing member 321 in a state in which the loading/unloading port 31b is not closed by the cover 32. Specifically, the additional capturer 53 captures the image of the sealing member 321 via the transparent member 52c and the second insertion hole 31g from above the exhaust duct 52 when the cover 32 is at the standby position.

As described above, the drying unit 18 according to the embodiment may capture the image of the sealing member 321 using the additional capturer 53, thus appropriately detecting whether or not an abnormality occurs in the sealing member 321. This makes it possible to suppress leakage of the processing fluid from the processing container 31 due to deterioration in the sealing member 321.

As described above, the drying unit 18 according to the embodiment may capture, by the capturer 41, the image of the capturing region including the loading/unloading port 31b and the processing space 31a of the processing container 31 exposed through the loading/unloading port 31b, thus appropriately detecting the internal state of the processing container 31. Thus, for example, when the wafer W is loaded into the processing container 31, the drying unit 18 may detect whether or not any other wafers remain in the processing container 31. This makes it possible to reduce the likelihood that the wafer W is damaged due to collision with other wafers.

### Detailed Operation of Substrate Processing Apparatus

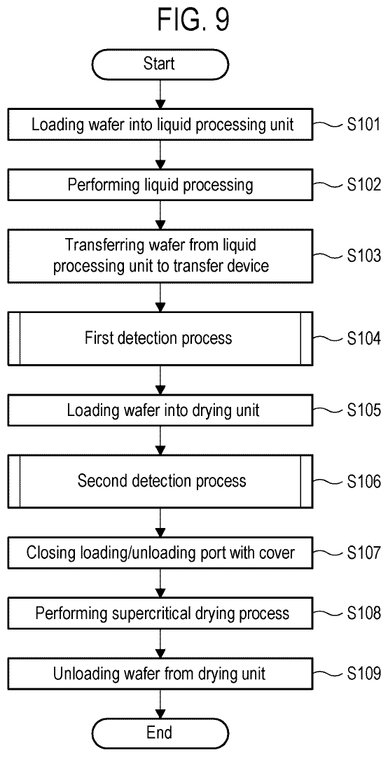

Next, a detailed operation of the substrate processing apparatus 1 will be described with reference to FIG. 9. FIG. 9 is a flowchart illustrating a process sequence executed by the substrate processing apparatus 1 according to the embodiment. In addition, FIG. 9 illustrates an example of the processing sequence from when the wafer W is loaded into the liquid processing unit 17 until the wafer W is unloaded from the drying unit 18. The process sequence illustrated in FIG. 9 is executed under control of the controller 71.

First, in the substrate processing apparatus 1, the transfer device 13 takes the wafer W out of the carrier C and places the same on the deliverer 14. Then, the transfer device 16 takes the wafer W from the deliverer 14 and loads the same into the liquid processing unit 17 (Operation S101).

Subsequently, in the substrate processing apparatus 1, the liquid processing unit 17 performs the liquid process on the wafer W (Operation S102). Specifically, the liquid processing unit 17 performs the cleaning process on the front surface of the wafer W with chemical liquid or the rinse liquid, and subsequently performs the liquid film formation process of supplying the IPA liquid to the front surface of the wafer W to form the liquid film.

Thereafter, in the substrate processing apparatus 1, the wafer W, which has been subjected to the liquid process, that is, the wafer W on which the liquid film is formed, is transferred from the liquid processing unit 17 to the transfer device 16 (Operation S103).

Subsequently, in the substrate processing apparatus 1, a first detection process of detecting an internal state of a first processing container is performed (Operation S104). Details of the first detection process will be described later.

Next, in the substrate processing apparatus 1, the wafer W is loaded into the drying unit 18 (Operation S105).

Specifically, the transfer device 16 unloads the wafer W from the liquid processing unit 17 while holding the wafer by using the wafer holding mechanism. Then, the transfer device 16 loads the wafer W held by the wafer holding mechanism from the loading/unloading port 31b of the drying unit 18 into the processing space 31a of the processing container 31. Subsequently, the transfer device 16 transfers the wafer W onto the support pins 34 inside the processing container 31. Thereafter, the transfer device 16 retracts the wafer holding mechanism.

Subsequently, in the substrate processing apparatus 1, a second detection process of detecting an internal state of a second processing container is performed (Operation S106). Details of the second detection process will be described later.

Subsequently, in the substrate processing apparatus 1, the drying unit 18 closes the loading/unloading port 31b with the cover 32 (Operation S107).

Specifically, the drying unit 18 uses the rotational mechanism 32a to rotate the cover 32 from the standby position (see FIG. 3) to the open position (see FIG. 4), and uses the linear motion mechanism 32b to move the cover 32 from the open position to the closed position (see FIG. 5). Thus, the loading/unloading port 31b of the processing container 31 is closed by the cover 32 to seal the processing space 31a. Subsequently, the drying unit 18 uses the lifting mechanism 51a to raise the locking member 51 so that the locking member 51 is inserted into the second insertion hole 31g formed in the second protrusion 31e.

Thereafter, in the substrate processing apparatus 1, the supercritical drying process is performed (Operation S108). Specifically, the drying unit 18 dries the wafer W, which has been subjected to the liquid film formation process, by bringing the wafer W into contact with the supercritical fluid.

Next, in the substrate processing apparatus 1, the transfer device 16 unloads the wafer W from the drying unit 18 (Operation S109). Specifically, the transfer device 16 holds the wafer W, which has been subjected to the supercritical drying process, using the wafer holding mechanism, and unloads the held wafer W from the drying unit 18. Thereafter, the transfer device 16 places the wafer W on the deliverer 14. The transfer device 13 takes the wafer W from the deliverer 14 and returns the same to the carrier C. In this way, a series of substrate processing on one sheet of wafer W is terminated.

### Details of First Detection Process of Detecting Internal State of First Processing Container

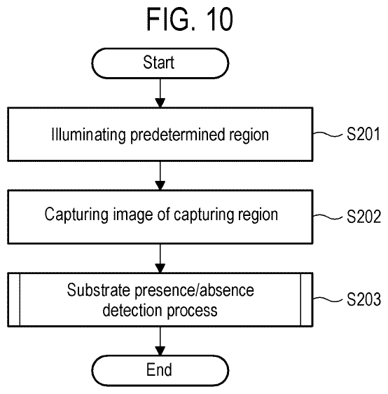

Next, details of the first detection process of detecting the internal state of the first processing container in Operation S104 will be described with reference to FIG. 10. FIG. 10 is a flowchart illustrating a sequence of the first detection process according to the embodiment. The first detection process illustrated in FIG. 10 is executed before Operation S105, that is, before the wafer W is loaded into the processing space 31a via the loading/unloading port 31b.

The controller 71 illuminates the predetermined region P around the loading/unloading port 31b in the capturing region using the illuminator 44 (Operation S201).

Next, the controller 71 captures an image of the capturing region using the capturer 41 (Operation S202). Specifically, the controller 71 captures the image of the capturing region including the loading/unloading port 31b and the processing space 31a of the processing container 31 exposed through the loading/unloading port 31b in a state in which the loading/unloading port 31b is not closed by the cover 32.

Then, the controller 71 performs a substrate presence/absence detection process of detecting whether or not the wafer W is present inside the processing container 31 based on a luminance value of the image captured by the capturer 41 (Operation S203).

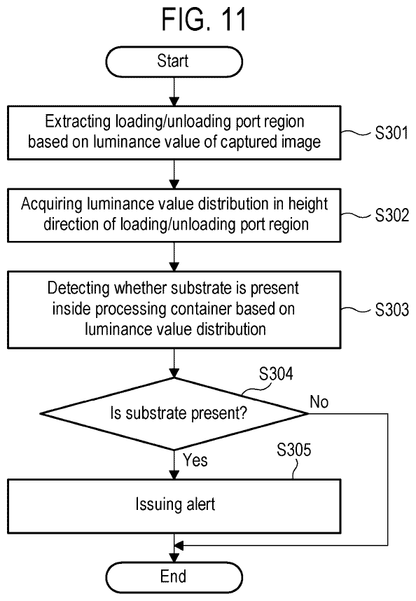

Details of the substrate presence/absence detection process will be described with reference to FIGS. 11 to 17. FIG. 11 is a flowchart illustrating a sequence of the substrate presence/absence detection process executed by the controller 71 according to the embodiment.

As illustrated in FIG. 11, in the substrate presence/absence detection process, first, the controller 71 executes a first process of extracting a loading/unloading port region corresponding to the loading/unloading port 31b from the capturing region, based on the luminance value of the image captured by the capturer 41 (Operation S301).

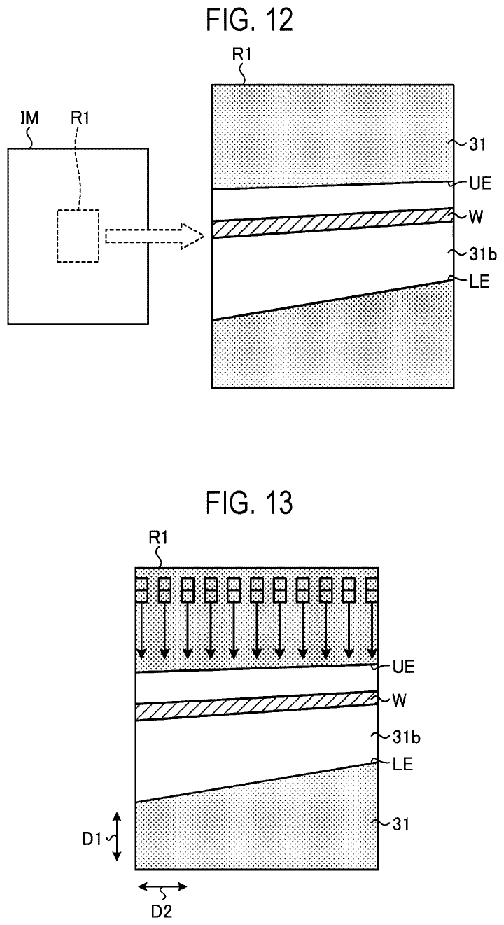

FIGS. 12 to 14 illustrate the first process according to an embodiment. Further, in FIGS. 12 to 14, an example in which the wafer W is present inside the processing container 31 is described.

For example, in the first process, as illustrated in FIG. 12, the controller 71 ternarizes a first region R1 including at least an upper edge UE and a lower edge LE of the loading/unloading port 31b in the capturing region, based on a luminance value of an image IM captured by the capturer 41. In addition, in FIG. 12, for the sake of convenience in description, the wafer W is hatched and the processing container 31 is shaded.

Next, as illustrated in FIG. 13, the controller 71 specifies the upper edge UE and the lower edge LE of the loading/unloading port 31b from the ternarized first region R1. In the example of FIG. 13, the controller 71 sets a pair of frames adjacent to each other in a height direction D1 (for example, the Z-axis direction) in a plurality of (ten in this example) of columns arranged in a width direction D2 (for example, the X-axis direction). Then, while lowering the pair of frames along the height direction D1, the controller 71 specifies, as the upper edge UE and lower edge LE of the loading/unloading port 31b, positions of pixels at which a difference between average luminance values within the pair of frames is equal to or greater than a threshold.

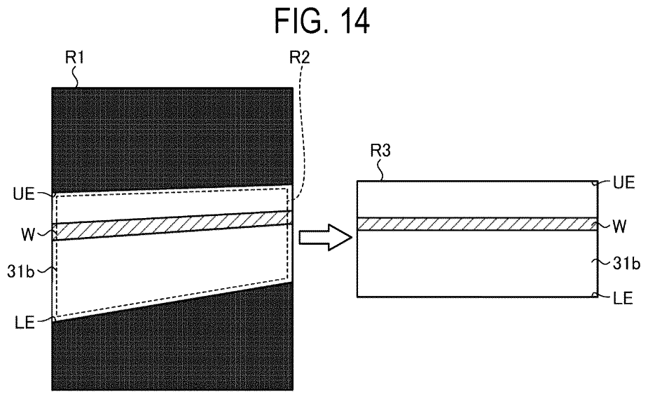

Next, as illustrated in FIG. 14, the controller 71 cuts out a second region R2 from the first region R1 using the specified upper edge UE and the specified lower edge LE of the loading/unloading port 31b, and performs a trapezoidal correction on the second region R2 to extract a load/unloading port region R3. Specifically, the controller 71 performs the trapezoidal correction on the second region R2 to correct distortion of the second region R2 caused by an arrangement position of the capturer 41, and extracts the loading/unloading port region R3. In the example of FIG. 14, the second region R2, which is distorted into a trapezoidal shape due to the arrangement position of the capturer 41, is corrected by the trapezoidal correction. Thus, the loading/unloading port region R3 of a rectangular shape is extracted. In this way, the first process is terminated.

Returning to the description of FIG. 11, subsequently in the substrate presence/absence detection process, the controller 71 performs a second process of acquiring a luminance value distribution in the height direction D1 (see FIG. 13) of the loading/unloading port region R3 (Operation S302).

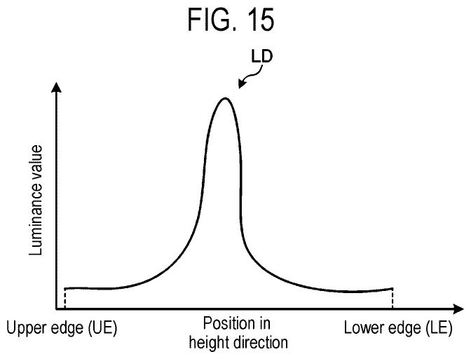

FIG. 15 illustrates the second process according to the embodiment. FIG. 15 illustrates a luminance value distribution LD in the height direction D1 of the loading/unloading port region R3. In the example of FIG. 15, the luminance value distribution LD is obtained by plotting an average luminance value at each position in the height direction D1 of the loading/unloading port R3 on a two-dimensional coordinate plane in which the horizontal axis represents a position in the height direction D1 and the vertical axis represents a luminance value. In the luminance value distribution LD in the height direction D1 of the loading/unloading port region R3, a luminance value corresponding to a position of the wafer W become larger than luminance values of other positions. Thus, a position in the height direction D1 of the loading/unloading port region R3, which corresponds to a maximum value in the luminance value distribution LD, is estimated as the position of the wafer W.

Returning to the description of FIG. 11, in the substrate presence/absence detection process, the controller 71 subsequently performs a third process of detecting whether or not the wafer W is present inside the processing container 31 based on the luminance value distribution LD in the height direction D1 of the loading/unloading port region R3 (Operation S303).

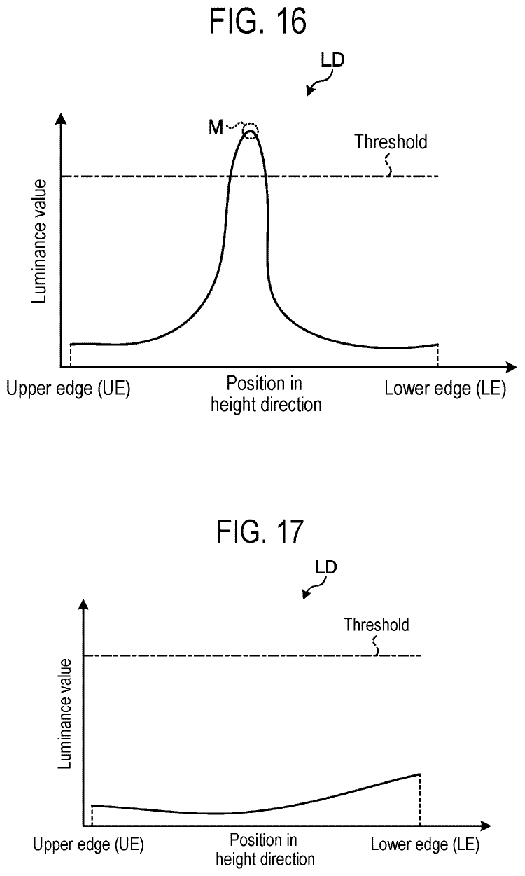

FIGS. 16 and 17 illustrate the third process according to the embodiment. FIG. 16 illustrates a luminance value distribution LD when the wafer W is present inside the processing container 31, and FIG. 17 illustrates a luminance value distribution LD when the wafer W is not present inside the processing container 31.

As illustrated in FIGS. 16 and 17, it can be seen that a maximum value M in the luminance value distribution LD becomes larger when the wafer W is present inside the processing container 31 than when the wafer W is not present inside the processing container 31.

Therefore, the controller 71 detects the presence or absence of the wafer W inside the processing container 31 based on the maximum value M in the luminance value distribution LD. Specifically, the controller 71 compares the maximum value M in the luminance value distribution LD with a predetermined threshold. When the maximum value exceeds the predetermined threshold, the controller 71 detects that the wafer W is present inside the processing container 31.

Returning to the description of FIG. 11, when the wafer W is detected to be present inside the processing container 31 (YES in Operation S304) from a result of the process in Operation S303, the controller 71 issues an alert (Operation S305) and terminates the process.

On the other hand, when the wafer W is detected to be not present inside the processing container 31 (NO in Operation S304), the controller 71 terminates the process without issuing the alert.

Further, when the wafer W is detected to be present inside the processing container 31, the controller 71 may stop the execution of the supercritical drying process and issue the alert. For example, the controller 71 may stop Operation S105 and subsequent Operations in FIG. 9 and issue the alert.

As described above, in the substrate presence/absence detection process according to the embodiment, the controller 71 detects the presence or absence of the wafer W inside the processing container 31 based on the luminance value of the image captured by the capturer 41.

Therefore, the internal state of the processing container 31 may be efficiently detected in comparison to the technique in the related art in which the captured image is compared with the reference image. That is, in the related art, it is necessary to compare the captured image with each reference image multiple times while switching the plurality of reference images according to internal states of the processing container 31. This makes it difficult to efficiently detect the internal state of the processing container 31.

In contrast, in the substrate presence/absence detection process according to the embodiment, the controller 71 detects the presence or absence of the wafer W inside the processing container 31 based on the luminance value of the image captured by the capturer 41. With this configuration, it is possible to detect the presence or absence of the wafer W inside the processing container 31 by using the luminance value of the captured image without switching the plurality of reference images or comparing the captured image with each reference image. Therefore, according to the embodiment, the internal state of the processing container may be efficiently detected.

### Details of Second Detection Process of Detecting Internal State of Second Processing Container

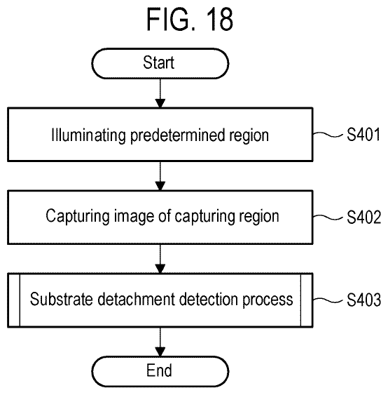

Next, details of the second detection process of detecting the internal state of the second processing container in Operation S106 will be described with reference to FIG. 18. FIG. 18 is a flowchart illustrating a sequence of the second detection process according to an embodiment. The second detection process illustrated in FIG. 18 is executed after the wafer W is loaded into the processing space 31a via the loading/unloading port 31b and before the loading/unloading port 31b is closed by the cover 32.

The controller 71 illuminates the predetermined region P around the loading/unloading port 31b in the capturing region using the illuminator 44 (Operation S401).

Next, the controller 71 captures an image of the capturing region using the capturer 41 (Operation S402). Specifically, the controller 71 captures the image of the capturing region including the loading/unloading port 31b and the processing space 31a of the processing container 31 exposed through the loading/unloading port 31b in the state in which the loading/unloading port 31b is not closed by the cover 32.

Next, the controller 71 performs a substrate detachment detection process of detecting whether or not the wafer W has been detached from the support pins 34 inside the processing container 31 based on the luminance value of the image captured by the capturer 41 (Operation S403).

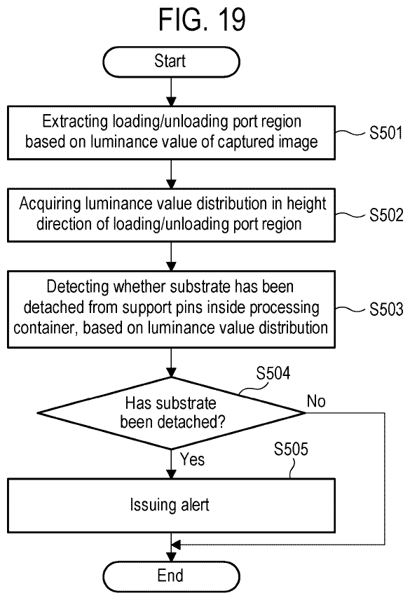

Hereinafter, details of the substrate detachment detection process will be described with reference to FIGS. 19 to 21. FIG. 19 is a flowchart illustrating a sequence of the substrate detachment detection process executed by the controller 71 according to an embodiment. Operations S501 and S502 in FIG. 19 are similar to Operations S301 and S302 described with reference to FIG. 11, and therefore detailed descriptions thereof will be omitted.

After the process of Operation S502, the controller 71 performs a third process of detecting whether or not the wafer W has been detached from the support pins 34 inside the processing container 31 based on the luminance value distribution LD in the height direction D1 of the loading/unloading port region R3 (Operation S503).

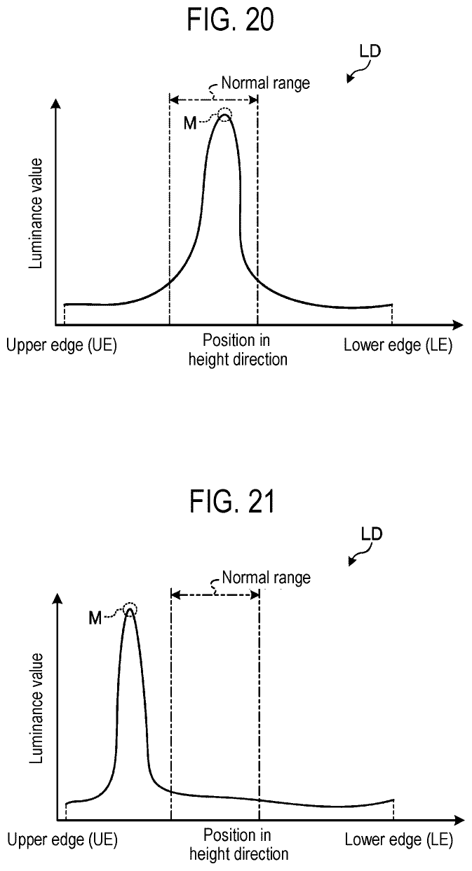

FIGS. 20 and 21 illustrate other examples of the third process according to an embodiment. FIG. 20 illustrates the luminance value distribution LD when the wafer W has not been detached from the support pins 34 inside the processing container 31. FIG. 21 illustrates the luminance value distribution LD when the wafer W has been detached from the support pins 34 inside the processing container 31.

As illustrated in FIGS. 20 and 21, it can be seen that, when the wafer W has been detached from the support pins 34 inside the processing container 31, a position of the loading/unloading port region R3 in the height direction D1, which corresponds to the maximum value M, is closer to the upper edge UE than when the wafer W has not been detached from the support pins 34.

Thus, the controller 71 compares the position of the loading/unloading port region R3 in the height direction D1, which corresponds to the maximum value M in the luminance value distribution LD, with a predetermined normal range, and when the position is determined to fall outside the predetermined normal range, detects that the wafer W has been detached from the support pins 34 inside the processing container 31.

Returning to the description of FIG. 19, as a result of the third process of Operation S503, when the wafer W is detected to be detached from the support pins 34 inside the processing container 31 (YES in Operation S504), the controller 71 issues an alert (Operation S505) and terminates the process.

On the other hand, when the wafer W is detected not to have been detached from the support pins 34 inside the processing container 31 (NO in Operation S504), the controller 71 terminates the process without issuing the alert.

Further, when the wafer W is detected not to have been detached from the support pins 34 inside the processing container 31, the controller 71 may stop the execution of the supercritical drying process and issue the alert. For example, the controller 71 may stop operations subsequent to Operation S107 in FIG. 9 and issue the alert.

### Modifications

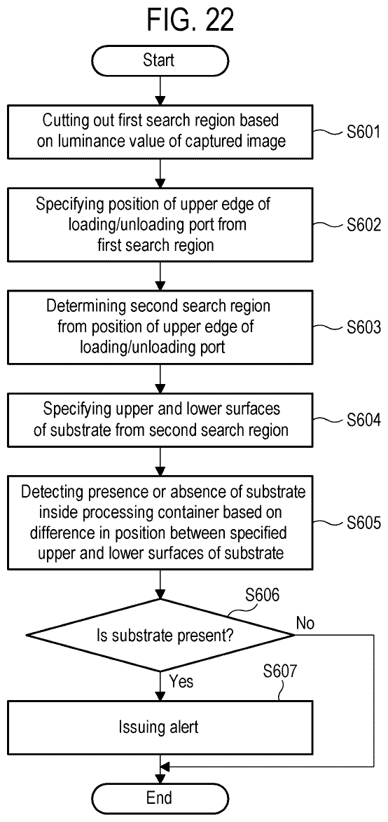

Next, various modifications of the embodiment will be described with reference to FIGS. 22 to 30. FIG. 22 is a flowchart illustrating a sequence of a substrate presence/absence detection process executed by the controller 71 according to Modification 1 of the embodiment.

As illustrated in FIG. 22, in the substrate presence/absence detection process, first, the controller 71 performs a fourth process of cutting out a first search region for searching for the upper edge UE of the loading/unloading port 31b from the capturing region based on the luminance value of the image captured by the capturer 41 (Operation S601).

FIG. 23 is an explanatory diagram illustrating the fourth process according to Modification 1 of the embodiment. In FIG. 23 and subsequent figures, an example in which the wafer W is present inside the processing container 31 will be described.

For example, in the fourth process, as illustrated in FIG. 23, the controller 71 binarizes the capturing region based on a luminance value of a captured image IM captured by the capturer 41, and cuts out a first search region R4 for searching for the upper edge UE of the loading/unloading port 31b from the binarized capturing region. In addition, in FIG. 23, for the sake of convenience in description, the wafer W and the processing container 31 are hatched.

Returning to the description of FIG. 22, in the substrate presence/absence detection process, the controller 71 performs a fifth process of specifying a position of the upper edge UE of the loading/unloading port 31b from the first search region R4 cut out as above (Operation S602).

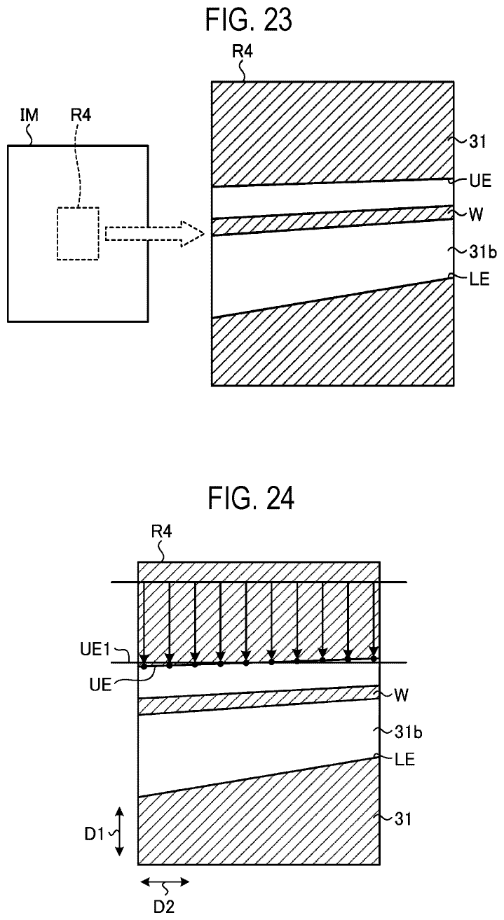

FIG. 24 is an explanatory diagram illustrating the fifth process according to Modification 1 of the embodiment. In the example of FIG. 24, the controller 71 sets luminance measurement points in a plurality of (ten in this example) columns arranged in a width direction D2 (for example, the X-axis direction). Then, the controller 71 measures luminance values at the luminance measurement points for each pixel while lowering the luminance measurement points in the height direction D1 and acquires positions of pixels at which a difference between measured luminance values exceeds a threshold value. Subsequently, the controller 71 specifies an average value of the acquired positions of the pixels as a position UE1 of the upper edge UE of the loading/unloading port 31b.

Returning to the description of FIG. 22, in the substrate presence/absence detection process, the controller 71 executes a sixth process of determining a second search region for searching for upper and lower surfaces of the wafer W from the specified position UE1 of the upper edge UE of the loading/unloading port 31b (Operation S603).

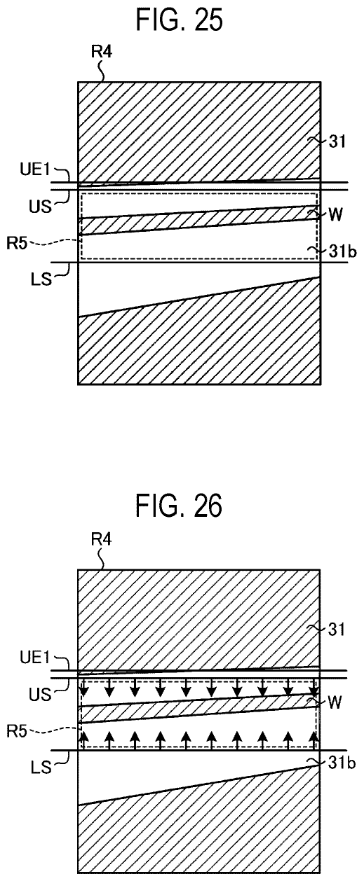

FIG. 25 is an explanatory diagram illustrating the sixth process according to Modification 1 of the embodiment. The controller 71 sets an upper side US at a position which is offset downward by a first number of pixels in the height direction D1 from the position UE1 of the upper edge UE of the loading/unloading port 31b, and sets a lower side LS at a position which is offset downward by a second number of pixels which is greater than the first number of pixels in the height direction D1 from the position of the upper side US. The controller 71 determines a region sandwiched between the upper side US and the lower side LS as a second search region R5.

Returning to the description of FIG. 22, in the substrate presence/absence detection process, the controller 71 executes a seventh process of specifying the upper and lower surfaces of the wafer W from the second search region R5 (Operation S604).

FIG. 26 is a diagram illustrating the seventh process according to Modification 1 of the embodiment. The controller 71 sets luminance measurement points in a plurality of (ten in this example) columns arranged in the width direction D2 (for example, the X-axis direction).

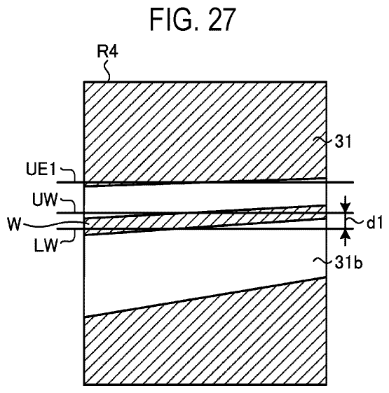

Subsequently, the controller 71 measures luminance values at the luminance measurement points for each pixel while lowering the luminance measurement points in the height direction D1 from the upper side US of the second search region R5, and acquires positions of pixels at which a difference between the measured luminance values exceeds a threshold value. Then, the controller 71 specifies an average value of the acquired positions of the pixels as a position UW of the upper surface of the wafer W (see FIG. 27). Further, the controller 71 measures luminance values at the luminance measurement points for each pixel while raising the luminance measurement points in the height direction D1 from the lower side LS of the second search region R5, and acquires positions of pixels at which a difference between the measured luminance values exceeds a threshold value. The controller 71 specifies an average value of the acquired positions of the pixels as a position LW of the lower surface of the wafer W (see FIG. 27). Further, when the luminance measurement point descending from the upper side US of the second search region R5 and the luminance measurement point ascending from the lower side LS of the second search region R5 overlap each other, the controller 71 sets a common position coordinate for the positions of the upper and lower surfaces of the wafer W. As the common position coordinate, for example, a midpoint position coordinate of a line segment orthogonal to the upper side US and the lower side LS is used.

Returning to the description of FIG. 22, in the substrate presence/absence detection process, the controller 71 executes an eighth process of detecting the presence or absence of the wafer W inside the processing container 31 based on the difference in position between the specified upper and lower surfaces of the wafer W (Operation S605).

FIG. 27 is an explanatory diagram illustrating the eighth process according to Modification 1 of the embodiment. The controller 71 determines whether or not a difference d1 (=|position UW−position LW|) between the positions of the upper and lower surfaces of the wafer W is greater than zero. When the difference dl is determined to be greater than zero, the controller 71 detects that the wafer W is present inside the processing container 31. On the other hand, when the difference d1 is determined to be zero, the controller 71 detects that the wafer W is not present inside the processing container 31. For example, when the common position coordinate is set for the positions of the upper and lower surfaces of the wafer W, the difference d1 becomes zero. Thus, the controller 71 detects that the wafer W is not present inside the processing container 31.

Returning to the description of FIG. 22, when the wafer W is detected to be present inside the processing container 31 (YES in Operation S606) from a result of the eighth process of Operation S605, the controller 71 issues an alert (Operation S607) and terminates the process.

On the other hand, when the wafer W is detected to be not present inside the processing container 31 (NO in Operation S606), the controller 71 terminates the process without issuing the alert.

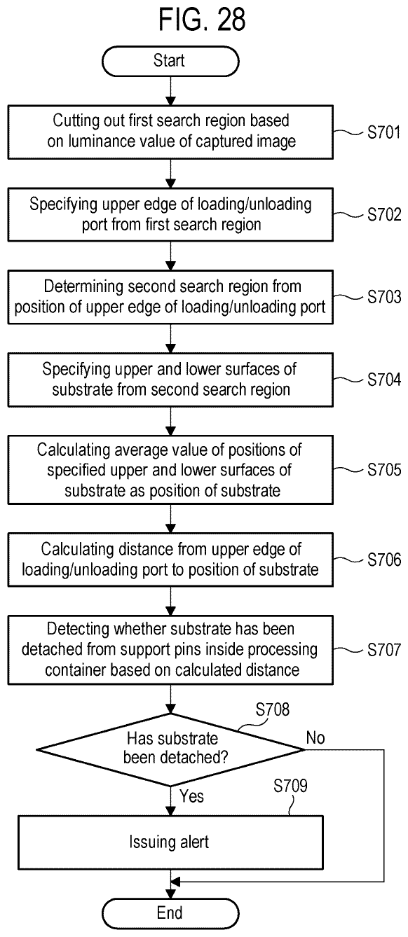

FIG. 28 is a flowchart illustrating a sequence of a substrate detachment detection process executed by the controller 71 according to Modification 2 of the embodiment. Operations S701 to S704 in FIG. 28 are similar to Operations S601 to S604 in FIG. 22, and therefore detailed descriptions thereof will be omitted.

After the process of Operation S704, in the substrate detachment detection process, the controller 71 executes a ninth process of calculating an average value of the positions of the specified upper and lower surfaces of the wafer W as the position of the wafer W (Operation S705).

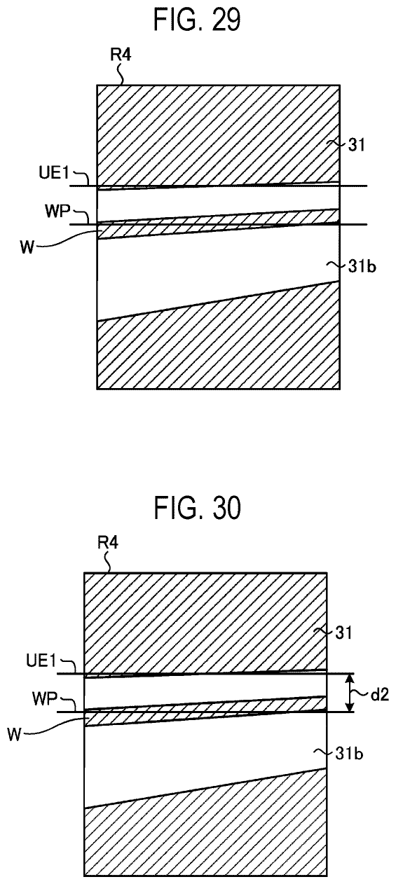

FIG. 29 is an explanatory diagram illustrating the ninth process according to Modification 2 of the embodiment. The controller 71 calculates the average value of the positions UW and LW of the upper and lower surfaces of the wafer W as a position WP of the wafer W.

Returning to the description of FIG. 28, in the substrate detachment detection process, the controller 71 executes a tenth process of calculating a distance from the position UE1 of the upper edge UE of the loading/unloading port 31b to the position WP of the wafer W (Operation S706).

FIG. 30 is an explanatory diagram illustrating the tenth process according to Modification 2 of the embodiment. The controller 71 calculates a distance d2 from the position UE1 of the upper edge UE of the loading/unloading port 31b to the position WP of the wafer W.

Returning to the description of FIG. 28, in the substrate detachment detection process, the controller 71 executes an eleventh process of detecting whether or not the wafer W has been detached from the support pins 34 inside the processing container 31 based on the calculated distance d2 (Operation S707). Specifically, the controller 71 compares the distance d2 with a predetermined normal range, and when the distance d2 is determined to fall outside the predetermined normal range, detects that the wafer W has been detached from the support pins 34 inside the processing container 31.

When the wafer W is detected to have been detached from the support pins 34 inside the processing container 31 (YES in Operation S708) from a result of the eleventh process of Operation S707, the controller 71 issues an alert (Operation S709) and terminates the process.

On the other hand, when the wafer W is detected to have not been detached from the support pins 34 inside the processing container 31 (NO in Operation S708), the controller 71 terminates the process without issuing the alert.

As described above, the substrate processing apparatus according to the embodiment (for example, the substrate processing apparatus 1) includes a processing container (for example, the processing container 31), a capturer (for example, the capturer 41), and a controller (for example, the controller 71). The processing container includes a processing space (for example, the processing space 31a) capable of accommodating a substrate (for example, the wafer W) and a loading/unloading port (for example, the loading/unloading port 31b) through which the substrate is loaded into and unloaded from the processing space. The capturer captures an image of a capturing region including the loading/unloading port and the processing space of the processing container exposed through the loading/unloading port. The controller detects a state of the substrate inside the processing container based on a luminance value of the image captured by the capturer.

Therefore, according to the substrate processing apparatus of the embodiment, it is possible to efficiently detect an internal state of the processing container.

### Others

In the above-described embodiments, an example has been described in which the capturer 41 is disposed at a position that does not overlap the transfer path R of the wafer W in a plan view. However, the capturer 41 may be configured to be movable between a capturing position on the transfer path R of the wafer W and a retracted position spaced apart from the transfer path R of the wafer W. In this case, before the wafer W is loaded into the processing space 31a via the loading/unloading port 31b, the capturer 41 moves from the retracted position to the capturing position to capture the capturing region at the capturing position.

Further, the capturer 41 may be provided in the transfer device 16. In this case, the transfer device 16 first loads the wafer W from the loading/unloading port 31b of the drying unit 18 into the processing space 31a of the processing container 31. The capturer 41 provided in the transfer device 16 captures an image of the capturing region before the loading/unloading port is closed by the cover 32.

According to the present disclosure in some embodiments, it is possible to efficiently detect an internal state of a processing container.

It should be noted that the embodiments and modifications disclosed herein are exemplary in all respects and are not restrictive. Indeed, the embodiments described herein may be embodied in various forms. Further, the above-described embodiments may be omitted, replaced, or modified in various forms without departing from the scope and spirit of the appended claims.

What is claimed is:

1. A substrate processing apparatus, comprising:
a processing container having a processing space capable of accommodating a substrate and a loading/unloading port through which the substrate is loaded into and unloaded from the processing space;
a capturer configured to capture an image of a capturing region including the loading/unloading port and the processing space of the processing container, which is exposed through the loading/unloading port; and
a controller configured to detect a state of the substrate inside the processing container based on a luminance value of the image captured by the capturer.

2. The substrate processing apparatus of claim 1, wherein the controller executes:
a first process of extracting a loading/unloading port region corresponding to the loading/unloading port from the capturing region based on the luminance value of the image;
a second process of acquiring a distribution of luminance values in a height direction of the extracted loading/unloading port region; and
a third process of detecting the state of the substrate inside the processing container based on the distribution of the luminance values in the height direction of the loading/unloading port region.

3. The substrate processing apparatus of claim 2, wherein, in the third process, the controller detects, as the state of the substrate, whether or not the substrate is present inside the processing container based on a maximum value in the distribution of the luminance values in the height direction of the loading/unloading port region.

4. The substrate processing apparatus of claim 1, wherein the controller detects, as the state of the substrate, whether or not the substrate is present inside the processing container based on the luminance value of the image captured by the capturer before the substrate is loaded into the processing space via the loading/unloading port.

5. The substrate processing apparatus of claim 2, wherein the processing container includes support pins provided on a bottom surface of the processing space to support the substrate, and
wherein, in the third process, the controller detects, as the state of the substrate, whether or not the substrate has been detached from the support pins inside the processing container based on a position in the height direction of the loading/unloading port region, which corresponds to a maximum value in the distribution of the luminance values in the height direction of the loading/unloading port region.

6. The substrate processing apparatus of claim 5, further comprising: a cover configured to be capable of closing the loading/unloading port,
wherein after the substrate is loaded into the processing space via the loading/unloading port and before the loading/unloading port is closed by the cover, the controller detects, as the state of the substrate, whether or not the substrate has been detached from the support pins inside the processing container based on the luminance value of the image captured by the capturer.

7. The substrate processing apparatus of claim 2, wherein, in the first process, the controller ternarizes a first region including at least an upper edge and a lower edge of the loading/unloading port in the capturing region based on the luminance value of the image, specifies the upper edge and the lower edge of the loading/unloading port from the ternarized first region, cuts out a second region from the first region using the specified upper edge and the specified lower edge of the loading/unloading port, and performs a trapezoidal correction on the second region to extract the loading/unloading port region.

8. The substrate processing apparatus of claim 7, wherein the capturer is disposed at a position that does not overlap a transfer path of the substrate with respect to the processing space via the loading/unloading port in a plan view, and
wherein the controller extracts the loading/unloading port region by performing the trapezoidal correction on the second region to correct distortion of the second region, which is caused by the position at which the capturer is disposed.

9. The substrate processing apparatus of claim 1, wherein the capturer is disposed at a position that does not overlap a transfer path of the substrate with respect to the processing space via the loading/unloading port in a plan view.

10. The substrate processing apparatus of claim 9, wherein the processing container includes:
a first protrusion formed below the loading/unloading port to protrude in an unloading direction in which the substrate is unloaded from the processing space via the loading/unloading port;
a second protrusion formed above the loading/unloading port to protrude in the unloading direction in which the substrate is unloaded from the processing space via the loading/unloading port; and
a shielding plate configured to shield a space between the first protrusion and the second protrusion,
wherein the shielding plate includes an opening formed at a position facing the loading/unloading port via the space and through which the substrate passes, and
wherein the capturer is disposed on an outer surface of the shielding plate, which is not in contact with the space and at a position adjacent to the opening along a width direction of the transfer path of the substrate.

11. The substrate processing apparatus of claim 10, wherein the shielding plate includes:
a through-hole formed adjacent to the opening along the width direction of the transfer path of the substrate; and
a transparent member configured to close the through-hole, and
wherein the capturer captures the image of the capturing region via the transparent member from the outer surface of the shielding plate.

12. The substrate processing apparatus of claim 10, wherein the shielding plate includes a partition wall disposed at a position surrounding an outer periphery of the opening on the outer surface of the shielding plate and configured to isolate the opening from the capturer.

13. The substrate processing apparatus of claim 10, further comprising: an illuminator configured to illuminate at least a predetermined region around the loading/unloading port in the capturing region.

14. The substrate processing apparatus of claim 13, wherein the shielding plate includes a plurality of through-holes arranged in the width direction of the transfer path of the substrate at positions facing the predetermined region around the loading/unloading port, and
wherein the illuminator includes:
a fixing plate provided at a position facing the plurality of through-holes in the shielding plate;
a light source fixed to the fixing plate; and
a light diffuser disposed between the fixing plate and the shielding plate and configured to diffuse light emitted from the light source in the width direction of the transfer path of the substrate and irradiate the predetermined region around the loading/unloading port with a portion of the diffused light via the plurality of through-holes.

15. A method of detecting an internal state of a processing container in a substrate processing apparatus,
wherein the substrate processing apparatus includes: the processing container having a processing space capable of accommodating a substrate and a loading/unloading port through which the substrate is loaded into and unloaded from the processing space; and a capturer configured to capture an image of a capturing region including the loading/unloading port and the processing space of the processing container, which is exposed through the loading/unloading port,
the method comprising:
capturing, by the capturer, the image of the capturing region; and
detecting a state of the substrate inside the processing container based on a luminance value of the image captured by the capturer.
